(19) United States
(12) Patent Application Publication
(10) Pub. No.: US 2008/0224932 A1
(43) Pub. Date: Sep. 18, 2008

(54) PORTABLE TERMINAL DEVICE

(76) Inventors: Eiji SUEMATSU, Nara-shi (JP); Miyoshi YAMAUCHI, Osaka-shi (JP); Motofumi YAMAGUCHI, Osaka-shi (JP)

Correspondence Address: BIRCH STEWART KOLASCH & BIRCH, PO BOX 747, FALLS CHURCH, VA, 22040-0747, US

(21) Appl. No.: 12/038,630

(22) Filed: Feb. 27, 2008

(30) Foreign Application Priority Data
Mar. 15, 2007 (JP) 2007-067527

(51) Int. Cl. H01Q 1/24; H05K 5/00

(52) U.S. Cl. 343/702; 361/679

(57) ABSTRACT

A portable terminal device can suppress/reduce a noise radiated from the portable terminal device, especially more effectively can suppress/reduce adverse effects of a high-frequency noise in VHF/UHF band or higher, so that reception sensitivity of its antenna can be improved effectively. The portable terminal device is arranged such that a sheet member includes at least one of a conductive sheet and a metal deposition sheet inside a housing, an electronic circuit substrate is provided inside the sheet material, and an antenna member is provided outside the sheet member.

This Nonprovisional application claims priority under 35 U.S.C. §119(a) on Patent Application No. 67527/2007 filed in Japan on Mar. 15, 2007, the entire contents of which are hereby incorporated by reference.

### FIELD OF THE INVENTION

The present invention relates to a portable terminal device such as a portable phone, a notebook PC, and a portable game machine.

### BACKGROUND OF THE INVENTION

Conventionally, a broadcasting receiving terminal device for a micro wave band, especially for UHF band, for example, a portable TV receiver for 400 MHz to 0.8 GHz band is usually equipped with a collapsing whip antenna. These days, digital circuits in a portable terminal device have speeded up, so that an electromagnetic noise (hereinafter referred to as noise) generated by CPUs and operation clocks ranges from a low frequency bandwidth to a high frequency bandwidth. Specifically, the frequency of the noise ranges extremely widely: from several hundred kHz to several GHz. Meanwhile, frequencies used for portable wireless communication terminals range from 0.07 GHz to 6 GHz in many cases, so that the electromagnetic noise acts as a noise source when the portable wireless communication terminals receive a transmission. In addition, the noise radiated through a housing adversely affects an antenna and an antenna cable of the terminal device. Consequently, when receiving, the noise is superimposed on a carrier. This lowers “a ratio of a carrier to noise”. As a result, the reception sensitivity considerably drops.

Japanese Unexamined Patent Publication No. 2002-158484 (Tokukai 2002-158484, published on May 31, 2002) (hereinafter referred to as Patent Document 1) discloses as follows.

Radio wave absorbers are used for absorbing an unwanted electromagnetic wave. By way of example, a radio wave absorber is arranged so that one or more magnetic layers contain a magnetic material having a nanogranular structure in which a grain diameter is controlled in the range of 1 nm to 100 nm. Another example is a radio wave absorber in which a conductor is fixed on a face of the magnetic layer, the face being opposite to a face where the unwanted electromagnetic wave is incident.

FIG. 8 is a perspective view schematically illustrating a configuration of a conventional portable terminal device. By way of example, as illustrated in FIG. 8, an outer housing 1001, in which a personal computer or a video camcorder is to be contained, consists of plated plastic, Al, Mg, or the like. In the outer housing 1001, a soft magnetic sheet 1000 is affixed on an inner surface for example, the soft magnetic sheet 1000 being formed by combining the magnetic material having the nanogranular structure with a macromolecular material or the like. The soft magnetic sheet 1000 functions as a cavity resonance suppressor.

In the case where the soft magnetic sheet 1000 has a thickness of about 0.3 mm to 2 mm for example, it generally has absorbing ability of about several dB against an electromagnetic wave with frequencies in the range from about 30 MHz to 2.5 GHz. According to Patent Document 1, in the case where the cavity resonance suppressor is placed in the outer housing 1001, a relatively wide area is required for the cavity resonance suppressor. However, the soft magnetic sheet 1000 can be made thinner than conventional sheets, so that the weight of the outer housing 1001 can be reduced.

In addition, in the above example, the radio wave absorber is formed in a sheet shape. However, the shape of the radio wave absorber using the magnetic material is not limited to the sheet shape. The radio wave absorber may be realized in various shapes depending on the device in which the radio wave absorber is to be placed. For example, according to Patent Document 1, a material in a paste form may be used for forming the magnetic layer.

In the magnetic wave absorbing sheet as described above, the power loss of a high frequency is increased, which power loss is generated by increasing magnetic permeability of a magnetic field. This effect only absorbs/reduces the high frequency component radiated to the magnetic wave absorbing sheet, so that the amount of the absorption/reduction, including the characteristics of the absorption/reduction, is limited. That is, at wide range of frequencies from 1 MHz to several GHz, 10 dB or more of absorption/reduction is difficult to obtain. This is attributed to a frequency characteristic of the magnetic permeability. In other words, this is attributed to a material characteristic.

With regard to the magnetic absorption, the following has been conventionally known.

With respect to the unwanted electromagnetic wave, electromagnetic fields can be divided into two types. One is a relatively near electromagnetic field where the distance between a wave source and a radio wave absorber is shorter than λ/6 (λ: wavelength of the electromagnetic wave). The other is a far electromagnetic field where the distance between the wave source and the radio wave absorber is longer than λ/6.

The radio wave absorber for the near electromagnetic field absorbs incoming electromagnetic wave by converting the energy of the electromagnetic wave into heat. The energy conversion is related to a loss term ε″ of the relative dielectric constant of the radio wave absorber (imaginary component of complex relative dielectric constant (dielectric loss)) and a loss term μ″ of the relative magnetic permeability of the radio wave absorber (imaginary component of complex relative magnetic permeability (magnetic loss)). In the case where the electromagnetic wave is radiated to a material that has these losses, the energy of the electromagnetic wave is converted to heat and then absorbed.

As a material has a greater loss, the material has a higher absorption capacity for the electromagnetic wave. However, a material has small ε″ in general, and a material that has been conventionally used for a radio wave absorber only has 10 in the value of μ″ with respect to the electromagnetic wave in a high frequency bandwidth of 1 GHz or more in particular. 10 in the value of μ″ is insufficient absorption capacity.

Meanwhile, with regard to the far electromagnetic field, in the case where an electromagnetic wave is radiated to the conventional material only once, normally not all of the energy of the electromagnetic wave is absorbed and converted to heat. This is because impedance of air and impedance of the radio wave absorber are not matched with each other at the front face of the radio wave absorber, so that the electromagnetic wave is reflected. Therefore, in the case where a radio wave absorber absorbs a plane wave from a long distance, an impedance-matching-type radio wave absorber is used. The impedance-matching-type radio wave absorber reduces the quantity of the reflected electromagnetic wave by matching wave impedance with input impedance to the radio wave absorber. In the impedance-matching-type radio wave absorber, the back face of the magnetic layer is lined with a conductor. By doing so, the reflected wave at the interface of the back face and the phase of the reflected wave at the front face of the radio wave absorber are controlled, so that these reflected waves cancel out each other. Therefore, the electromagnetic wave is absorbed. Normally, the impedance-matching-type radio absorber can attenuate 20 dB of the reflected wave. The 20 dB attenuation indicates that 99 percent of the energy of the electromagnetic wave is absorbed.

However, in the above arrangement, an electromagnetic absorbing layer requires a thickness of about λ/4. Therefore, the electromagnetic absorbing layer cannot be used in a common portable terminal device. In the case where the distance between the wave source of a noise and a radio wave absorber is shorter than λ/6 (λ: wavelength of an electromagnetic wave), the noise can be suppressed to some extent by taking a shielding measure locally or by placing the radio wave absorber locally. However, the noise is not comprehensively suppressed. In addition, noises are, in many cases, generated from a substrate per se, from a flexible cable heavily used for a portable device, and from a driver circuit, which circuit takes over a wide area behind the liquid crystal display of the portable device. Therefore, it is difficult to take the shielding measure locally or to use the radio wave absorber. Therefore, in a housing, in many cases, the noise with a component of the far electromagnetic field, in which the distance between the wave source and the radio wave absorber is longer than λ/6, is dominant.

As described above, with regard to the far electromagnetic field, in the case where the electromagnetic wave is radiated to the conventional material only once, not all of the energy of the electromagnetic wave is absorbed and converted to heat. This is because the impedance of air and the impedance of the radio wave absorber are not matched with each other at the front face of the radio wave absorber so that the electromagnetic wave is reflected. Therefore, in the case where a portable terminal device includes a substrate, an electronic circuit, a cable, or the like, which is larger in area than λ/6, it is not possible to absorb the electromagnetic wave with attenuation of 20 dB or more. Therefore, it is not effective to only take means of simply absorbing the electromagnetic wave.

### SUMMARY OF THE INVENTION

The present invention was made in view of the foregoing problems. An object of the present invention is to provide a portable terminal device capable of suppressing/reducing a radiation noise from the portable terminal device, especially, more effectively suppressing/reducing adverse effects of a high-frequency noise in VHF/UHF band or higher so that reception sensitivity of its antenna can be improved effectively.

In order to achieve the object, a portable terminal device of the present invention includes a sheet member including at least one of a conductive sheet and a metal deposition sheet, the sheet member being provided inside a housing of the portable terminal device.

With the arrangement, the conductive sheet or the metal deposition sheet is provided inside the housing. Therefore, the radiation high-frequency noise from a substrate and an electronic components is firstly radiated into air from electronic components such as CPUs and clocks in each digital circuit, a cable, or a substrate. Then, the radiation high-frequency noise is radiated to the housing through space/air.

In the case where the sheet member provided inside the housing is the conductive sheet, the radiation high-frequency noise is reflected to the circuit substrate side. As a result, leakage of the radiation high-frequency noise to the outside of the housing is reduced to extremely small. Since a ground treatment such as via holes on a main body substrate and the like, and a shield treatment are provided over the entire substrate, the radiation high-frequency noise changes to an electrical current which runs into the ground.

In addition, the metal deposition sheet not only reflects the radiation high-frequency noise, but also absorbs the radiation high-frequency noise to some extent. Therefore, the metal deposition sheet can further reduce the leakage of the radiation high-frequency noise to the outside of the housing.

Furthermore, the conductive sheet or the metal deposition sheet may be connected to the ground in the same electric potential as the main body substrate in the entire housing. In addition, the conductive sheet or the metal deposition sheet may not be connected to the ground or the like provided on the substrate or the like so that the conductive sheet or the metal deposition sheet has an electric potential different from that of the ground.

With the arrangement as described above, adverse effects to another portable wireless device that are caused by the high-frequency noise radiated from the inside of the portable terminal device can be reduced. In addition, adverse effects of the noise coming from the outside can be reduced.

In order to achieve the object, another portable terminal device of the present invention includes a sheet member including at least one of a conductive sheet and a metal deposition sheet, the sheet member being provided outside a housing of the portable terminal device.

With the arrangement, the sheet member is provided outside the housing. Therefore, by attaching the conductive sheet or the metal deposition sheet to the outside of an existing terminal device, it is possible to reflect the high-frequency noise from the inside of the housing of the existing terminal device or to reflect the high-frequency noise and absorb some of the high-frequency noise. Therefore, noise radiated from the exiting terminal device can be reduced/controlled. Part of the components of the radiation high-frequency noise having been reflected here is radiated through a gap of the sheet member or permeates to the inside of the housing. By controlling a manner by which the gap is provided, a direction in which the noise leaks out can be controlled. Therefore, it is possible to put an antenna in the best position where the noise is small. As a result, a transmission/reception characteristic of the antenna can be improved.

In order to achieve the object, further another portable terminal device of the present invention includes a sheet member in which a conductive sheet and a metal deposition sheet are alternately laminated, the sheet member being provided at a housing of the portable terminal device.

With the arrangement, by laminating the sheet members alternately, reflectance is increased. In addition, by laminating the sheet members alternately, reflection and absorption are repeated, so that the leakage of the electromagnetic wave to the outside of the housing is reduced. As a result, it is possible to reduce the effects of the electromagnetic wave on another portable wireless device. In addition, adverse effects of the electromagnetic noise coming from the outside can be reduced.

Additional objects, features, and strengths of the present invention will be made clear by the description below. Further, the advantages of the present invention will be evident from the following explanation in reference to the drawings.

### BRIEF DESCRIPTION OF THE DRAWINGS

FIGS. 1(a) and 1(b) are cross-sectional views schematically illustrating a configuration of a portable terminal device of Embodiment 1. FIG. 1(a) illustrates an entire cross-section and FIG. 1(b) illustrates a cross-section of a main part.

FIG. 2 is a perspective view schematically illustrating a portable terminal device of Embodiment 2.

FIG. 3 is a perspective view schematically illustrating the portable terminal device of Embodiment 2.

FIGS. 4(a) and 4(b) are perspective views schematically illustrating a configuration of an antenna member provided in the portable terminal device. FIG. 4(a) illustrates a configuration in which a whip antenna is in use and FIG. 4(b) is a configuration in which the whip antenna is housed.

FIGS. 5(a) and 5(b) are perspective views schematically illustrating a configuration of another antenna member provided in the portable terminal device. FIG. 5(a) illustrates a configuration in which a whip antenna is in use and FIG. 5(b) illustrates a configuration in which the whip antenna is housed.

FIG. 6 is a graph illustrating noise characteristics in the portable terminal device.

FIG. 7 is a graph illustrating noise characteristics in the portable terminal device.

FIG. 8 is a perspective view schematically illustrating a configuration of a conventional portable terminal device.

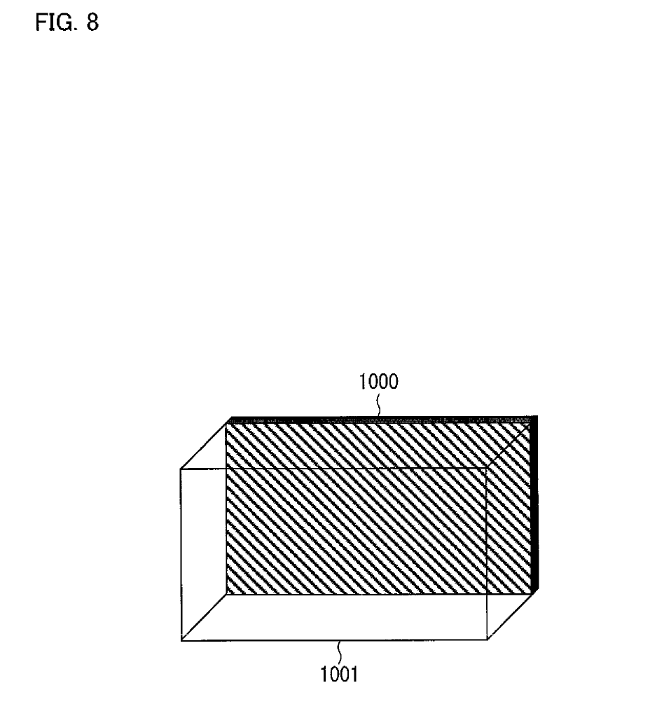

### DESCRIPTION OF THE EMBODIMENTS

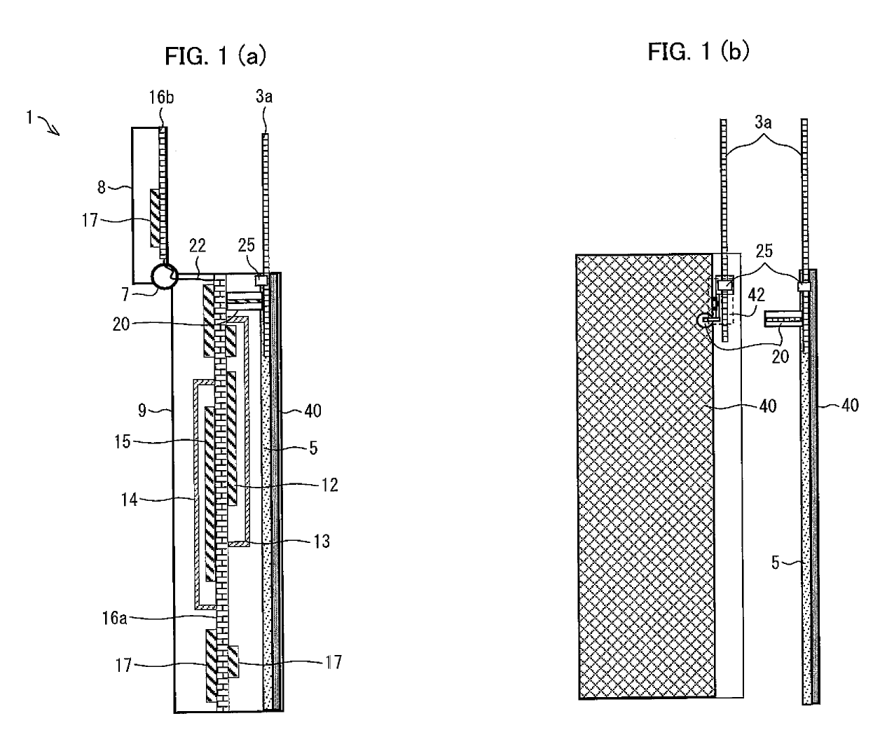

Embodiments of the present invention are described below with reference to FIGS. 1 to 7.

### Embodiment 1

FIGS. 1(a) and 1(b) are cross-sectional views schematically illustrating a configuration of a portable terminal device 1 of Embodiment 1.

The portable terminal device 1 includes, at its outer side, a housing 8 with insulation properties made of resin or the like, a housing 9 with insulation properties made of resin and others, and a hinge segment 7, which joints the housing 8 and the housing 9 together. The housing 9 has a whip antenna 3a having a rod shape. The whip antenna 3a is connected via an antenna fixation terminal 25 to a power feeding section on an antenna substrate 40. The power feeding section is provided with a matching circuit 42. An output section of the matching circuit 42 is connected to a circuit substrate 16a via a coaxial connector 20. In addition, ground of the output section of the matching circuit 42, a ground section on the antenna substrate 40, and ground of the circuit substrate 16a are connected to ground of the coaxial connector 20. The coaxial connector 20 is connected with a tuner IC 12 or the like on the substrate 16a. In the tuner IC 12, a required signal is chosen and demodulated. The demodulated signal is subjected to a digital signal process and is displayed on a liquid crystal display section. In addition, on the antenna substrate 40, a metal deposition sheet 5 is provided on a side which faces the circuit substrate 16a. Each metal deposition sheet 5 is a thin layer with a thickness of 10 μm to 30 μm and has surface resistance of several hundred kΩ/□ to several MΩ/□. By way of example, in the present embodiment, the metal-evaporated sheet 5 of thin layer may be a copper tape, an aluminum foil, or an aluminum tape. Furthermore, the metal deposition sheet 5 may be a composite sheet in which a metal deposition sheet of a thin layer having surface resistance of several hundred kΩ/□ to several MΩ/□ is combined with a conductive sheet.

In the present embodiment, the metal deposition sheet 5 is affixed on the antenna substrate 40 so as to be positioned on a surface which faces the internal circuit substrate 16a. The metal deposition sheet 5 is a thin layer and has surface resistance of several hundred kΩ/□ to several MΩ/□. Specifically, an Al vapor-evaporated sheet 5 having surface resistance of several MΩ/□ is used in the present embodiment.

A high-frequency electromagnetic noise is once radiated into air from the tuner IC 12 and electronic components 15 and 17 such as CPU or clock of each digital circuit, cable 22, and the substrates 16a and 16b. Then, radiated into the housing 8 and 9 through space/air (or nitrogen).

As described above, by providing a metal deposition sheet 5 of a thin layer having surface resistance of several hundred kΩ/□ to several MΩ/□, the high-frequency electromagnetic noise is reflected in a direction of the circuit substrate 16a. Consequently, the leakage of the high-frequency electromagnetic noise to the outside of the housing 9 is reduced immensely. In addition, in the case where ground treatments such as a metal patterning and a via hole are provided on the substrate 16a, or shielding plates 13 and 14 are provided over whole of the substrate 16a, the reflected noise changes into an electrical current which runs into the ground. Furthermore, by using the Al vapor-evaporated sheet 5 with high resistance, even if a part of electronic circuits or a wiring section touches the Al vapor-evaporated sheet 5, electric characteristics do not change so much.

Furthermore, in the case where the Al vapor-evaporated sheet 5 is a single sheet made of a single Al vapor-evaporated sheet 5, not all of the components of the noise are reflected, and some of the components are transmitted. Therefore, a composite sheet is preferable, the composite sheet being arranged so that the Al vapor-evaporated sheets 5 are combined with each other, or the Al vapor-evaporated sheet 5 is combined with another kind of sheet. In addition, a composite sheet in which a thin film conductive sheet made of Al or Cu is combined with the high-resistive Al vapor-evaporated sheet 5 is more preferable.

In the case where the composite sheet is arranged so that a high-reflectance conductive sheet is combined with a high-resistive reflective sheet that has some absorption effects, the noise is more effectively prevented from leaking to the outside of the housings 8 and 9. In addition, the high-resistive reflective sheet is very convenient for the following reasons: even if the high-resistive reflective sheet touches electrical circuits, the high-resistive reflective sheet does not cause short-circuit, even if the high-resistive reflective sheet touches a human body, the high-resistive reflective sheet does not cause hazards such as an electric shock or the like, and the high-resistive reflective serves to prevent static electrical charge.

### Embodiment 2

The present embodiment has the same configurations as Embodiment 1 except for configurations as described below. In addition, for convenience of explanation, the same referential numerals are applied to members having the same functions as the members illustrated in the drawings for Embodiment 1, and are not explained again.

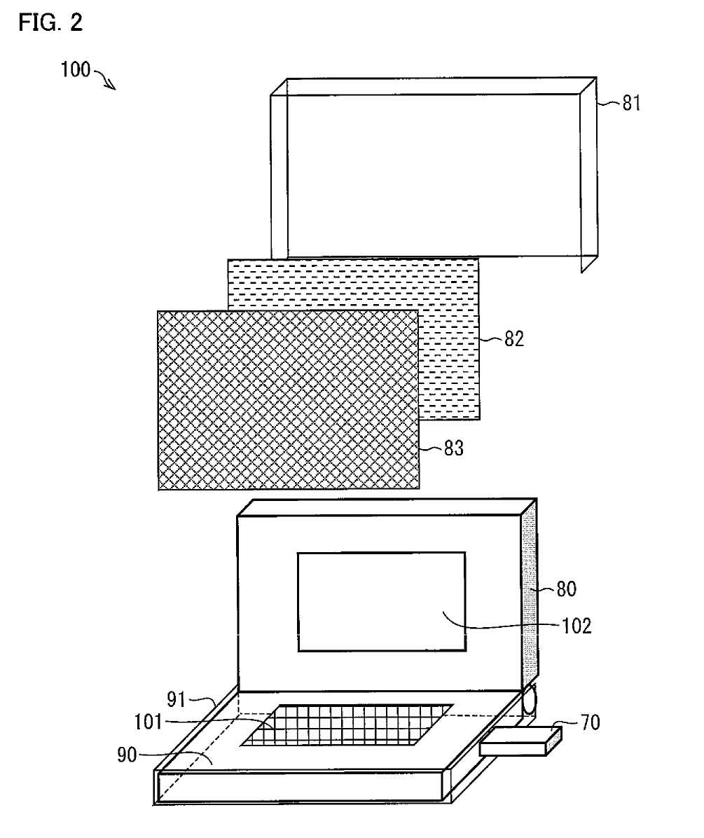

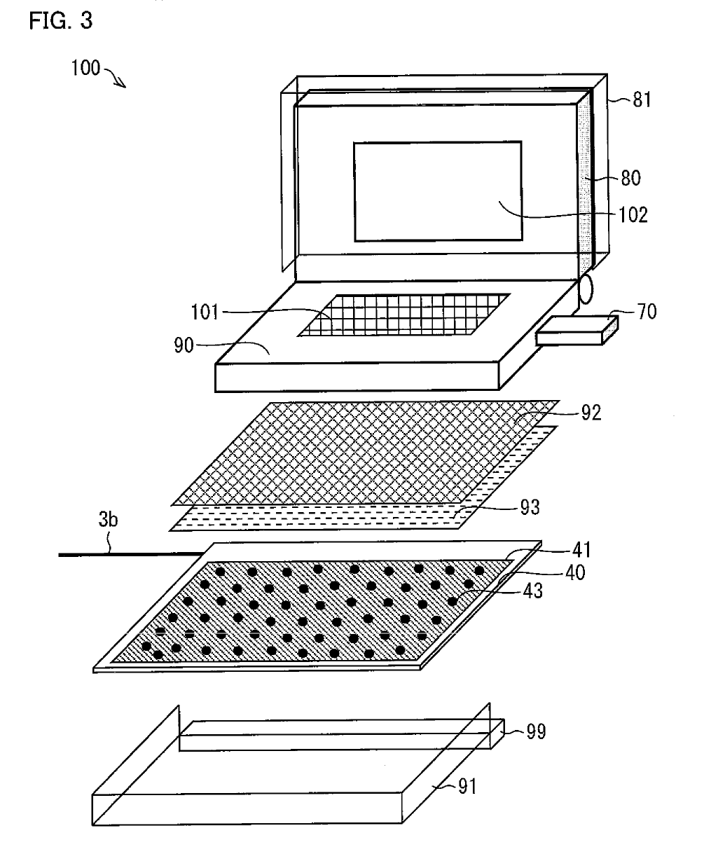

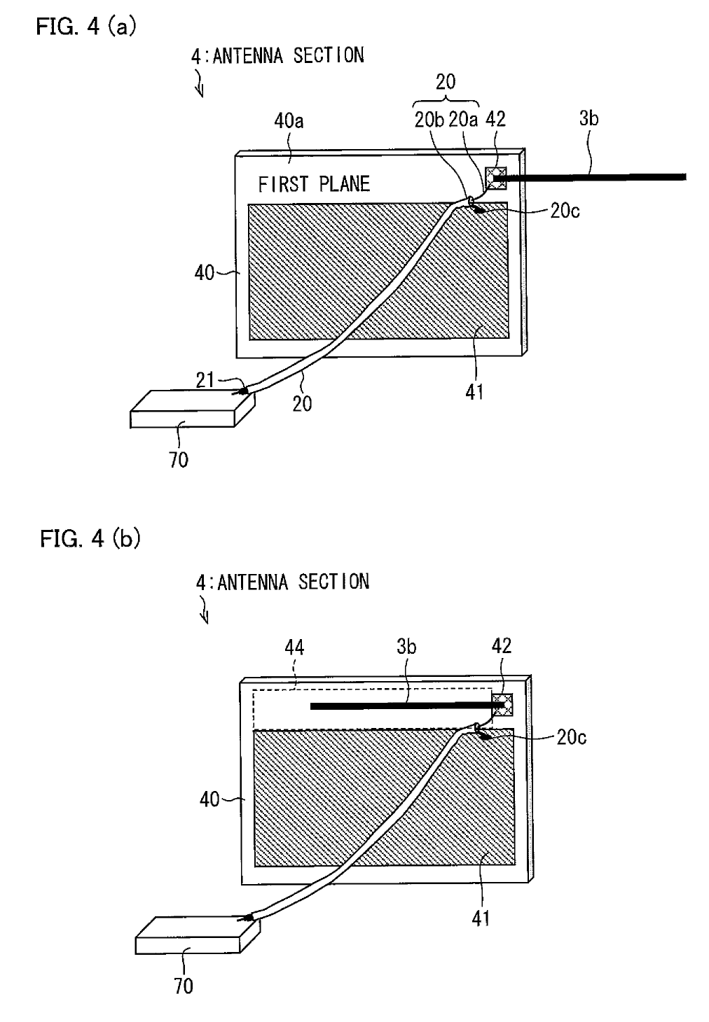

FIGS. 2 and 3 are perspective views schematically illustrating configurations of a portable terminal device 100 of Embodiment 2. FIGS. 4(a) and 4(b) are perspective views schematically illustrating a configuration of an antenna member 4 provided in the portable terminal device 100.

The portable terminal device 100 of Embodiment 2 is an existing portable terminal device. For example, the portable terminal device 100 is a portable terminal device such as a notebook PC, an electronic personal organizer, a game machine, or the like to which an external radio transmitting/receiving device such as a USB card, a cartridge, or the like is attached. Housings 80 and 90 of the portable terminal device 100 are made of insulators such as resin or the like. The portable terminal device 100 is not limited to this. The terminal device of the present invention is not limited to a portable type such as the portable terminal device 100, but may be applied to so called stationary-type terminal devices such as a stationary TV, a stationary PC, and the like. In the present embodiment, compare to Embodiment 1 in which the tuner section and the antenna section are built-in types, the existing portable terminal device 100 is attached with a tuner cartridge 70 as an external module.

The portable terminal device 100 includes a display section 102 provided in the upper housing 80 and a keyboard section 101 provided in the lower housing 90. By way of example, a receiving tuner cartridge 70 is attached to the side of the lower housing 90 of the portable terminal device 100. The receiving tuner cartridge 70 is arranged so that a connecting cable 20 (in FIG. 4(a)) to be connected to a whip antenna 3b is connected to a ground pattern 41 of an antenna substrate 40 and a power feeding section 42 of the whip antenna 3b.

FIG. 2 illustrates a configuration of an upper protective case 81 that is to be attached to the portable terminal device 100. The upper protective case 81 is made of resin, plastic or the like. The upper protective case 81 is arranged so that a high-resistive Al vapor-evaporated sheet 82 of a thin layer having surface resistance of 100 kΩ/□ to several MΩ/□ is affixed to the inside of the upper protective case 81, and a conductive sheet 83 such as an aluminum foil, an Al tape, and a Cu tape is affixed and fixed on the Al vapor-evaporated sheet 82. The upper protective case 81 covers the upper housing 80 with double-faced tape or the like.

The antenna member 4 or the like is not directly provided in the upper protective case 81. However, a noise generated from the inside of the terminal housing 80 is reflected by the conductive sheet 83 and the high-resistive Al vapor-evaporated sheet 82, and a part of the noise is absorbed. As a result, the noise around the upper protective case 81 is reduced.

FIG. 3 illustrates a series of the configuration of a lower protective case 91 to be attached to the portable terminal device 100 and the antenna member 4 provided to the lower protective case 91. The lower protective case 91 is made of resin, plastic, or the like. Inside of the lower protective case 91, an antenna substrate 40 is provided, the antenna substrate 40 including an antenna 3b, a power feeding circuit 42 (FIG. 4(a)), and a ground pattern 41. On the upper side of the antenna substrate 40, between the antenna substrate 40 and the housing 90 of the portable terminal device 100, a high-resistive Al vapor-evaporated sheet 93 of a thin layer having surface resistance of several hundred kΩ/□ to several MΩ/□ is affixed. A conductive sheet 92 such as an aluminum foil, an Al tape, and a Cu tape is affixed and fixed on the high-resistive Al vapor-evaporated sheet 93. The protective case 91 covers the housing 90 with a double-faced tape, or the like. In addition, the antenna substrate 40 is connected to the tuner cartridge 70 via the coaxial cable 20 or the like.

As described above, the protective cases 81 and 91 protect the upper housing 80 and the lower housing 90, respectively. However, a protective case that wraps up and protects the upper housing 80 and the lower housing 90 may be used. In addition, as another example, a carrying case provided with a strap, a shoulder string, or the like for portability may be used.

It is more preferable that the protective case or the carrying case includes a storing section 99 for containing a whip antenna, so that the antenna section can be contained and protected.

In addition, although it is not illustrated in the drawings, the whip antenna 3b has a pin for fixing the whip antenna 3b. The pin may be provided on the antenna substrate 40 or in the protective case 91 with a screw. In addition, in the case where the pin is provided in the protective case 91, an insertion frame (not shown) may be formed with resin or the like in the housing 90. Furthermore, as the conductive sheet 92 and the high-resistive metal deposition sheet 93 having surface resistance of several hundred kΩ/□ to several MΩ/□ are provided, so that the protective case or the carrying case functions as a cushion for protecting the portable terminal device 100. As a result, the protection for the portable terminal device 100 is improved, while the receiver sensitivity is improved as described above. In addition, a section for storing the whip antenna 3b can be arranged.

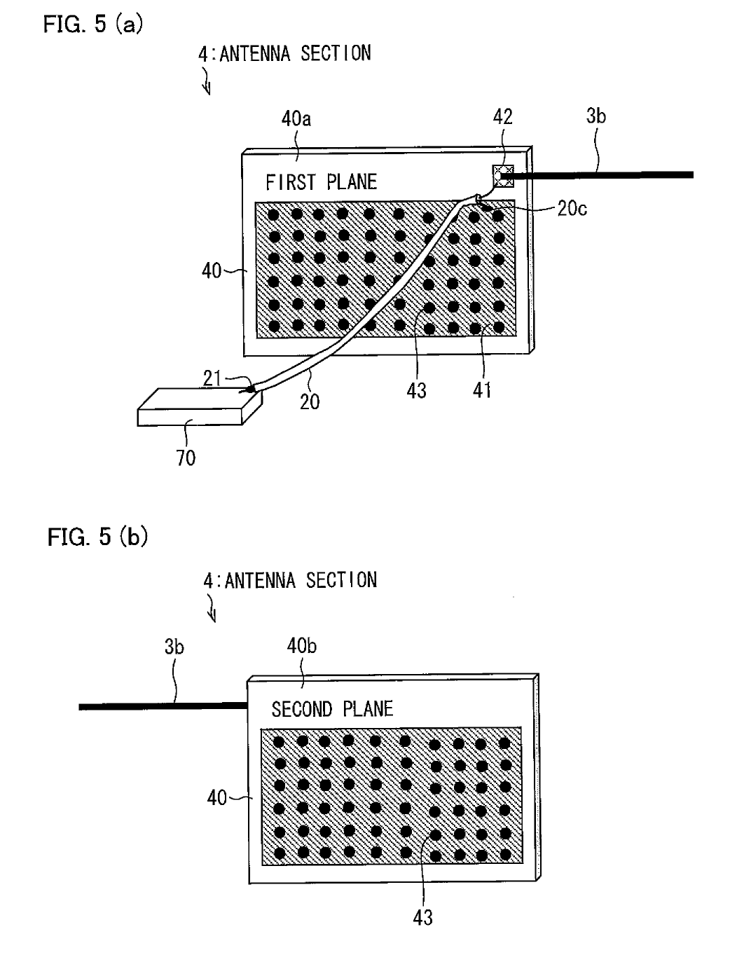

FIGS. 4 and 5 illustrate a detailed configuration of the antenna substrate 40. As illustrated in FIG. 4, the antenna substrate 40 is made of a dielectric substrate wherein a ground pattern 41 is provided on a first plane 40a. In this case, a back plane of the first plane (a second plane) may be a metal pattern which is electrically connected to nowhere, or single-sided metal pattern where the dielectric substrate is exposed.

In the present embodiment, by way of example, FIG. 4(a) illustrates a state where the whip antenna 3b is used and the whip antenna 3b is extended, and FIG. 4(b) illustrates a state where the whip antenna 3b is housed. As illustrated in FIG. 4(b), an insulator region 44 patterned without metals is formed so that the whip antenna 3b does not touch the ground pattern 41 on the antenna substrate 40 when the whip antenna 3b is housed in the protective case 91. Therefore, even when the whip antenna 3b is housed, although its receiver sensitivity is a little lower than when extended, the whip antenna 3b can operate as an antenna. As a result, even if the whip antenna is housed, it can operate in an area where a reception radio wave is an intense electric field.

In this configuration, a power feeding section 42 for the antenna is connected with a coaxial central conductor 20a, and the ground pattern 41 is connected with a coaxial outer conductor 20b via a touching section 20c. The antenna section is connected with the tuner cartridge 70 by the coaxial cable 20 via a connector 21 that is detachable.

In addition, although FIGS. 4(a) and 4(b) are simplified for convenience of explanation, the power feeding section 42 may include a matching circuit, a low-noise amplifier, or and the like (not shown).

In addition, the whip antenna 3b, for example, for receiving a terrestrial broadcasting has a length of about 13 cm, and a long side of the ground pattern 41 of the antenna substrate 40 also has a length of about 13 cm. Consequently, the ground section has a limited length, and is different from ground that ideally has an unlimited area. Therefore, the antenna member 4 operates as a pseudo dipole antenna. Therefore, it is possible to provide the power feeding section 42 with a balun, so that the power feeding section 42 may operate as a dipole antenna, which is closer to the ideal antenna, including a balance side having two antennas 3b/41, and the unbalance side as an unbalance mode of the coaxial cable 20.

FIGS. 5(a) and 5(b) are perspective views schematically illustrating a configuration of other antenna member provided in the portable terminal device 100. According to the configuration, an antenna substrate 40 includes a double-sided metal pattern in which a ground pattern 41 is formed on a first plane 40a and the other ground pattern 41 is formed on a second plane 40b. The ground pattern 41 on the first plane 40a and the other ground pattern 41 on the second plane 40b are connected with each other via multiple via holes 43. The via holes 43 are arranged so that the intervals in distance between each of the via holes 43 are shorter enough than a length that is 0.25 times longer than the wavelength of an operating frequency (by way of example, the interval is shorter than a wavelength of 0.05). Since each of the ground patterns 41 shunts each other in high-frequently, the effective metal thickness of the ground patterns 41 is approximately the same as the thickness of the antenna substrate 40. Therefore, in the case where the ground patterns 41 operate as an antenna, the ground patterns 41 become an excellent emitter. As described above, when receiving a terrestrial broadcasting, the portable terminal device 100 operates as a dipole antenna, so that the ground patterns 41 also operate as an antenna. Therefore, an excellent performance can be obtained as the dipole antenna.

The antenna member 4 is placed in the lower housing 91 in the present embodiment. However, the antenna member 4 may be placed in the upper housing 80. In this case, of course, the conductive sheet 92 and the metal vapor-deposited sheet 93 are placed between the antenna member 4 and the upper housing 80.

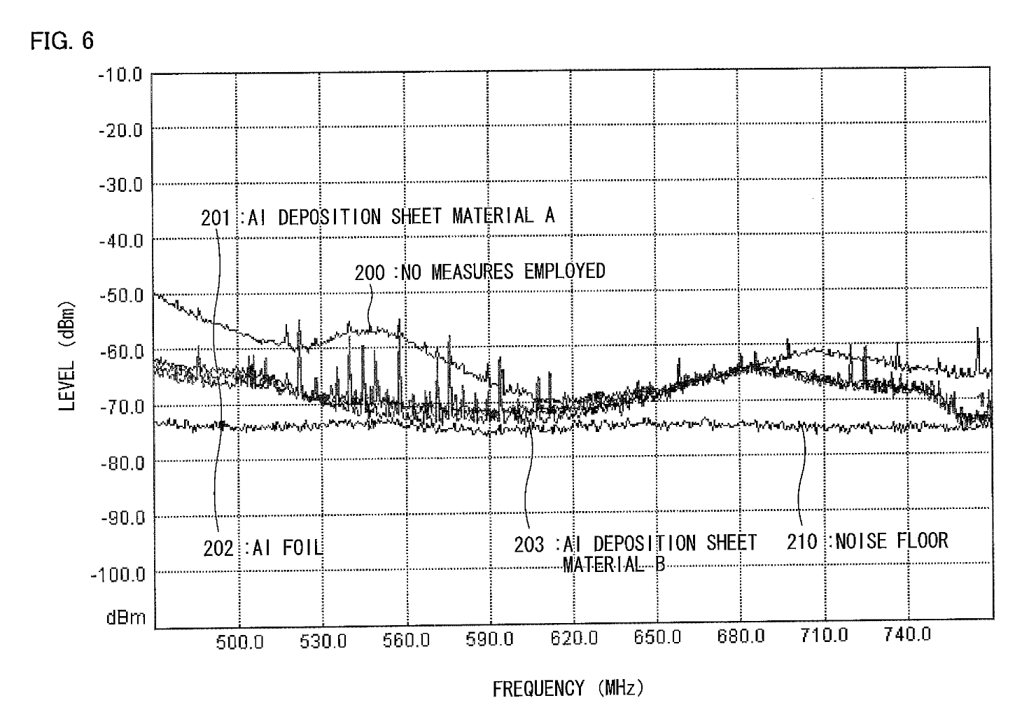

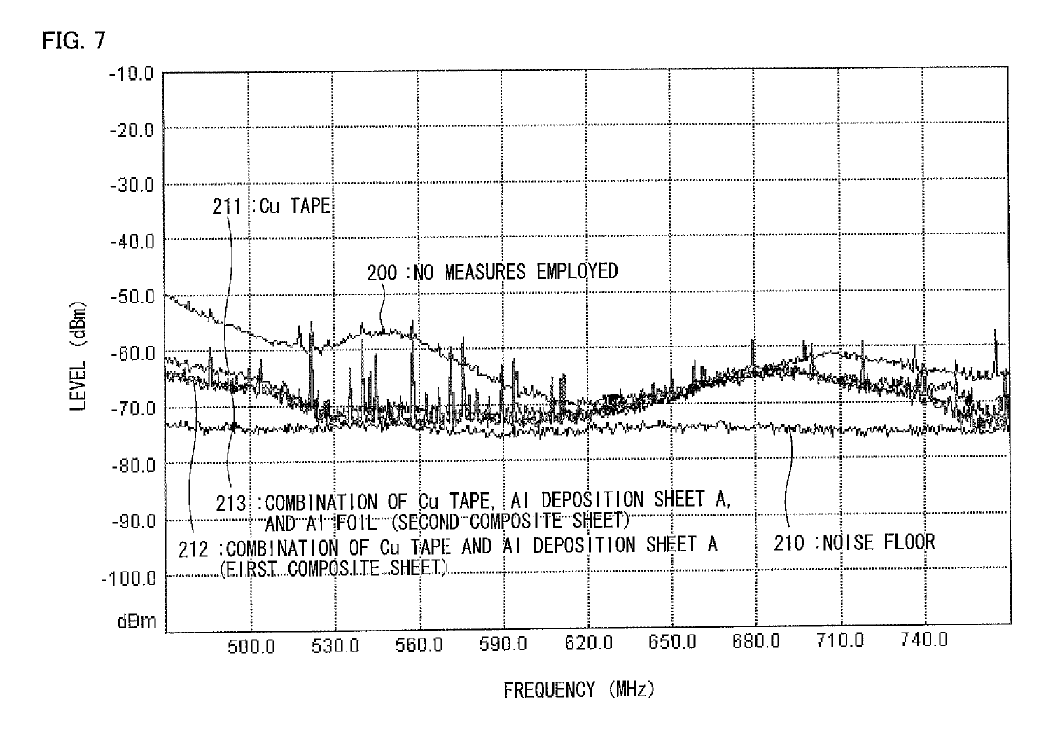

With reference to FIGS. 6 and 7, the following explains a noise reducing effect against the noise from the inside of the portable terminal device 100 of the present embodiment.

FIG. 6 illustrates frequency spectrum characteristics. The vertical axis represents an electrical power level (dBm) and the horizontal axis represents a frequency (MHz). FIG. 6 shows: a noise floor 210 of a measurement system (equivalent to approximately 3 dB in the noise index); and a noise electrical power level 200 at a time when the noise from the portable terminal device 100 is received by a standard dipole antenna which is 1 cm away from the portable terminal device 100, the portable terminal device 100 being provided with no measures against the noise. In the broadcasting frequency band for a terrestrial TV broadcasting, i.e. 470 MHz to 770 MHz, a large high-frequency noise, 23 dB or larger at maximum, is received and detected. A frequency characteristic 202 of a noise electrical power level is measured in the case where only a sheet of aluminum foil (Al foil) having, for example, a thickness of about a dozen μm as a conductive sheet material, or the conductive sheet 83 or the conductive sheet 92 is placed between the portable terminal device 100 and the lower housing 90 as described above. By applying the Al foil, the noise electrical power level is reduced by about 13 dB at maximum in a certain frequency and comes closer to the noise floor characteristic 210.

In addition, a frequency characteristic 201 of a noise electrical power level and a frequency characteristic 203 of a noise electrical power level are illustrated in FIG. 6. The frequency characteristic 201 or the frequency characteristic 203 is measured in the case where an Al vapor-deposited sheet A or B is used as a high-resistive Al vapor-deposited sheet 93, the Al vapor-deposited sheet 93 being a thin layer (about few dozens μm in thickness) and having a surface resistance of several MΩ/□. Although, it differs by about 2 dB according to the frequency, it exhibits approximately the same noise-electrical-power-level reducing effect as the Al foil 202.

As with FIG. 6, FIG. 7 shows: a noise floor 210 of a measurement system (equivalent to about 3 dB in noise index); and a noise electrical power level 200 of a portable terminal device 100 at a time when the noise from the portable terminal device 100 is received by a standard dipole antenna which is 1 cm away from the portable terminal device 100, the portable terminal device 100 being provided with no measures against the noise. Furthermore, FIG. 7 illustrates a noise electrical power level characteristic 211 in the case where copper tape having a thickness of about 20 μm is used as the conductive sheet 83 or 92. The noise electrical power level characteristic 211 exhibits the same noise-electrical-power-level reducing effect as the frequency characteristic 202 of FIG. 6 in which the Al foil is used.

In addition, FIG. 7 illustrates a noise electrical power level characteristic of a composite sheet, in which a conductive sheet 83/92 and a high-resistive sheet 82/93 are combined. By way of example, a noise electrical power level characteristic 212 of a first composite sheet in which the high-resistive Al vapor-deposited sheet A used in FIG. 6 and a copper tape are combined is shown. The noise-electrical-power-level is reduced by 3 dB or more at maximum in a case where the first composite sheet is applied than a case where the only a sheet of copper tape is applied. This could be mainly because the composite sheet can improve the reflectance.

In addition, FIG. 7 illustrates a noise electrical power level characteristic 213 of a second composite sheet in which the first composite sheet is further attached with a sheet of Al foil. The first composite sheet and the second composite sheet exhibit the similar noise electrical power level characteristic.

As described above, in the case where the conductive sheet 83/92 and the high-resistive sheet (metal vapor-deposited sheet) 82/93 are combined to make a composite sheet, the reflectance is improved. Furthermore, since the high-resistive sheet has some noise absorption effects, several more dB of the noise is reduced.

Meanwhile, with respect to the noise suppressive/reducing effect, the noise electrical power level is reduced by the effect of reflection. Therefore, it is not likely that the more composites sheets are combined, the more the noise electrical power level is reduced. Conversely, the reflectance of the sheets may be deteriorated. As a result, the noise electrical power level may be increased.

As described above, the portable terminal devices of Embodiment 1 and Embodiment 2 can reduce the electromagnetic noise coming from the electronic circuits/substrates in the housings of the portable terminal devices. Therefore, the portable terminal devices can improve the receiver sensitivity of the antenna. In addition, by appropriately controlling the direction of a gap in the attached sheet materials, a direction to which the electromagnetic noise is emitted can be controlled, and the antenna and the ground plate can be placed in a direction in which the noise is small. As a result, the receiver sensitivity of the antenna can be improved. In addition, by shielding a surface of the ground plate which surface faces the electronic circuit/substrate, the electromagnetic noise from the electronic circuit/substrate becomes less likely to mount on the ground plate. Therefore, excellent receiver sensitivity can be obtained.

The sheet material for portable terminal devices of Embodiment 1 and Embodiment 2 can be placed not only in the housing, but also in an external carrying case or an external protective case. Therefore, the sheet material can be provided to an exiting portable terminal device. As a result, excellent receiver sensitivity can be obtained.

The present invention is applicable to portable terminal devices such as portable phones, notebook PCs, and portable game machines. The present invention can improve the receiver sensitivity of portable terminal devices such as notebook PCs. In addition, the present invention is effective in dealing with issues related to EMC

### (Electro Magnetic Compatibility).

It is preferable to arrange the portable terminal device of the present embodiment so that an electronic circuit substrate is provided inside the sheet member, and an antenna member is provided outside the sheet member.

With the arrangement, the sheet material is provided outside the housing, and the antenna member is provided outside the sheet material. Therefore, the noise radiated from the electronic circuit/substrate in the housing can be reduced. Therefore, adverse effects of the noises to the antenna member can be reduced/suppressed. As a result, the antenna member can achieve sensitive transmission/reception.

It is preferable to arrange the portable terminal device of the present embodiment so that the antenna member includes a conductive plate and a power feeding section.

With the arrangement, the sheet material is provided outside the housing, and the antenna member including the conductor plate and the power feeding section are provided outside the sheet material. Therefore, with the sheet material, the antenna member having the power feeding section and the conductor plate can reduce/suppress the noise from the electronic circuit and the substrate. That is, the antenna member and the conductor plate can reduce/suppress adverse effects of the noise from the portable terminal device. The conductor plate operates as a ground plate. In comparison with the reception wavelength (λ), the size of the ground plate is limited. That is, the ground plate is not an unlimitedly wide and ideal ground plate. Therefore, the conductor plate operates as a dipole antenna which contributes to radiation from the ground plate.

As a result, sensitive transmission/reception can be achieved. In addition, by using the sheet material, an antenna element (e.g. whip antenna) projecting from its housing to the outside reduces/suppresses the noise coming from the inside of the housing. Therefore, the noise surrounding the whip antenna is also suppressed/reduced. Therefore, in the case of using the sheet material, the portable terminal device can obtain higher “carrier to noise ratio” in comparison with a portable terminal device without the sheet material. As a result, the portable terminal device can obtain better reception sensitivity characteristics.

It is preferable to arrange the portable terminal device of the present embodiment so that the antenna member further includes a whip antenna projecting from the housing, the conductive plate includes a conductive layer covered with a metal pattern on a dielectric substrate to which the whip antenna is attached, and the whip antenna is provided on the dielectric substrate so as to be positioned on an insulator region where the metal pattern is removed, so that the whip antenna is housed and dragged out freely.

With the arrangement, the ground metal pattern is removed from the section that houses the antenna. In addition, the section is provided with the insulator region. Therefore, even in the case where the whip antenna is housed in the section having the insulator region, the whip antenna can operate as an antenna. For example, when using the portable terminal device in an area that has huge reception electric field intensity, the portable terminal device can operate having the antenna housed therein. Therefore, the portable terminal device has following advantages: it does not need to pull out the antenna for use, the antenna is not obstructive, and the antenna is less likely to be bent or broken.

It is preferable to arrange the portable terminal device of the present embodiment so that the conductive layer includes a first metal layer formed on a first plane and a second metal layer formed on a second plane, and the first metal layer and the second metal layer are connected with each other via holes.

With the arrangement, the ground plate is, as a ground plate of the antenna element, a ground plate that has a limited space. Therefore, the ground plate operates as a dipole antenna contributing to radiation. Therefore, by connecting both the first metal layer and the second layer via holes, the ground plate that has a limited space can have a wider surface area. As a result, excellent receiver characteristics can be obtained.

It is preferable to arrange the portable terminal device of the present embodiment so that the sheet member is provided inside a protective case or carrying case for protecting the housing.

With the arrangement, the conductive sheet or the metal deposition sheet is provided inside the protective case or the carrying case. Therefore, the protective case or the carrying case operates as a cushioning material for protecting the portable terminal device and a material for keeping the temperature of the portable terminal device constant. Therefore, the housing is provided with stronger protection and kept away from a sudden temperature change. This allows stability and higher reception sensitivity. Furthermore, a section for housing the antenna can be provided.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

1. A portable terminal device, comprising a sheet member including at least one of a conductive sheet and a metal deposition sheet, the sheet member being provided inside a housing of the portable terminal device.

2. A portable terminal device, comprising a sheet member including at least one of a conductive sheet and a metal deposition sheet, the sheet member being provided outside a housing of the portable terminal device.

3. A portable terminal device, comprising a sheet member in which a conductive sheet and a metal deposition sheet are alternately laminated, the sheet member being provided at a housing of the portable terminal device.

4. The portable terminal device as set forth in claim 1, wherein an electronic circuit substrate is provided inside the sheet member, and an antenna member is provided outside the sheet member.

5. The portable terminal device as set forth in claim 4, wherein the antenna member includes a conductive plate and a power feeding section.

6. The portable terminal device as set forth in claim 5, wherein the antenna member further includes a whip antenna projecting from the housing, the conductive plate includes a conductive layer covered with a metal pattern on a dielectric substrate to which the whip antenna is attached, and the whip antenna is provided on the dielectric substrate so as to be positioned on an insulator region where the metal pattern is removed, so that the whip antenna is housed and dragged out freely.

7. The portable terminal device as set forth in claim 6, wherein the conductive layer includes a first metal layer formed on a first plane and a second metal layer formed on a second plane, and the first metal layer and the second metal layer are connected with each other via holes.

8. The portable terminal device as set forth in claim 2, wherein the sheet member is provided inside a protective case or carrying case for protecting the housing.

9. The portable terminal device as set forth in claim 2 wherein an electronic circuit substrate is provided inside the sheet member, and an antenna member is provided outside the sheet member.

10. The portable terminal device as set forth in claim 3 wherein an electronic circuit substrate is provided inside the sheet member, and an antenna member is provided outside the sheet member.

11. The portable terminal device as set forth in claim 3, wherein the sheet member inside a protective case or carrying case for protecting the housing member.
